(19) United States
(12) Patent Application Publication
(10) Pub. No.: US 2026/0271263 A1
(43) Pub. Date: Sep. 10, 2026

(54) COMPOSITE SILICIDE FOR 3D DRAM DEVICES

(71) Applicant: Applied Materials, Inc., Santa Clara, CA (US)

(72) Inventors: Ying-Bing JIANG, Woodland, CA (US); Joung Joo LEE, San Jose, CA (US); Xianmin TANG, San Jose, CA (US)

(21) Appl. No.: 19/069,709

(22) Filed: Mar. 4, 2025

(51) Int. Cl. H10B 12/00

(52) U.S. Cl. CPC H10B 12/30; H10B 12/05

(57) ABSTRACT

A semiconductor structure includes a layer stack on a substrate, wherein an opening extends through the layer stack, inner surfaces of the opening comprising silicon surfaces and dielectric surfaces, and a composite metal silicide layer on the silicon surfaces of the opening, wherein the composite metal silicide layer comprises titanium-incorporated molybdenum silicide.

### BACKGROUND

### Field

Embodiments described herein generally relate to semiconductor device fabrication, and more particularly, to methods of forming metal silicide.

### Description of the Related Art

The production of silicon integrated circuits has placed difficult demands on fabrication processes to increase the number of devices while decreasing the minimum feature sizes on a chip. These demands have extended to fabrication processes including depositing layers onto difficult topologies while maintaining device reliability. For example, in three dimensional (3D) dynamic random access memory (DRAM) devices or multi-gate metal-oxide-semiconductor field-effect transistors (MOSFETs), such as complementary metal-oxide semiconductor (CMOS) devices, metal silicide (e.g., molybdenum silicide (MoSiₓ), titanium silicide (MoSiₓ), ruthenium silicide (RuₓSi_{y})) is often utilized to lower contact resistivity. However, such metal silicides have issues and challenges. For example, titanium silicide (TiSiₓ) provides a low contact resistivity and good thermal stability during subsequent fabrication processes, but lacks good selectivity (silicon surfaces vs. dielectric surfaces) and uniformity on inner sidewalls of deep holes or deep trenches along the depth of the holes/trenches. Molybdenum silicide (MoSiₓ) provides good selectivity and uniformity when deposited, but lacks a low contact resistivity and thermal stability during subsequent fabrication processes.

Therefore, there is a need for material and methods of forming thereof that can be used as metal silicide having good selectivity and uniformity when deposited on inner sidewalls of deep holes or deep trenches, and providing a low contact resistivity and thermal stability.

### SUMMARY

Embodiments of the present disclosure provide a semiconductor structure. The semiconductor structure includes a layer stack on a substrate, wherein an opening extends through the layer stack, inner surfaces of the opening comprising silicon surfaces and dielectric surfaces, and a composite metal silicide layer on the silicon surfaces of the opening, wherein the composite metal silicide layer comprises titanium-incorporated molybdenum silicide.

Embodiments of the present disclosure also provide a method of forming a composite metal silicide layer in a semiconductor structure. The method includes performing a silicide deposition process in a processing chamber, in which a metal silicide layer of silicide of a first metal is selectively formed on silicon surfaces within an opening formed in a semiconductor structure, inner surfaces of the opening comprising the silicon surfaces and dielectric surfaces, and performing an incorporation process in the processing chamber, in which a second metal is incorporated into the metal silicide layer, wherein the first metal comprises molybdenum (Mo) and the second metal comprises titanium (Ti).

Embodiments of the present disclosure further provide a method of forming a composite metal silicide layer in a semiconductor structure. The method includes removing contaminants on silicon surfaces within an opening formed in a semiconductor structure, inner surfaces of the opening comprising the silicon surfaces and dielectric surfaces, depositing a metal silicide layer comprising silicide of a first metal on the silicon surfaces within the opening using a precursor containing the first metal at a first deposition temperature, incorporating a second metal into the metal silicide layer using a precursor containing the second metal at a second deposition temperature, depositing a cap layer on the metal silicide layer, and performing a post annealing process.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic top view of a multi-chamber processing system according to one or more embodiments of the present disclosure.

FIG. 2 depicts a process flow diagram of a method of forming and post-treating a metal silicide layer in a semiconductor structure according to one or more embodiments of the present disclosure.

FIGS. 3A, 3A′, 3B, 3B′, 3C, and 3C′ are cross-sectional views of a portion of a semiconductor structure corresponding to various states of the method of FIG. 2.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The embodiments described herein provide composite metal silicide (e.g., titanium (Ti)-incorporated molybdenum silicide (MoSiₓ: Ti)) and methods for forming thereof within a deep opening (e.g., a hole or a trench) that can be used to reduce a contact resistance in three dimensional (3D) dynamic random access memory (DRAM) devices or multi-gate metal-oxide-semiconductor field-effect transistors (MOSFETs). The composite metal silicide (e.g., titanium (Ti)-incorporated molybdenum silicide (MoSiₓ: Ti)) provides benefits of both of single-composition silicides (e.g., molybdenum silicide (MoSiₓ) and titanium silicide (TiSiₓ)), having good selectivity, uniformity, and thermal stability when deposited on inner sidewalls of deep holes or deep trenches, and providing a low contact resistivity.

The methods of forming composite metal silicide include first forming metal silicide (e.g., molybdenum silicide (MoSiₓ)) that can ensure good selectivity, and then incorporating additional metal species (e.g., titanium (Ti)) to improve contact resistivity and thermal stability.

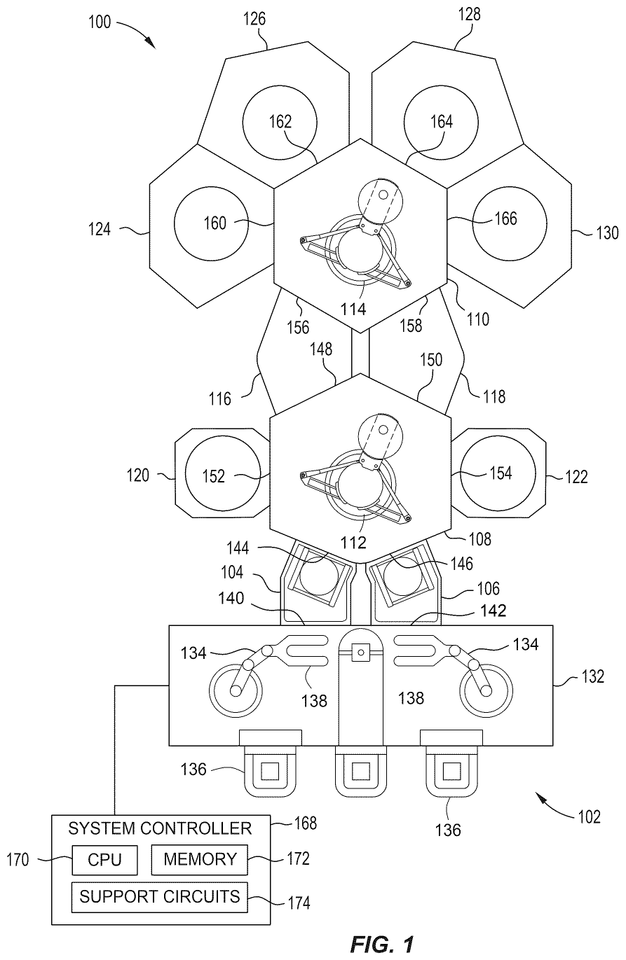

FIG. 1 is a schematic top view of a multi-chamber processing system 100, according to one or more embodiments of the present disclosure. The processing system 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, substrates in the processing system 100 can be processed in and transferred between the various chambers without exposing the substrates to an ambient environment exterior to the processing system 100 (e.g., an atmospheric ambient environment such as may be present in a fab). For example, the substrates can be processed in and transferred between the various chambers maintained at a low pressure (e.g., less than or equal to about 300 Torr) or vacuum environment without breaking the low pressure or vacuum environment among various processes performed on the substrates in the processing system 100. Accordingly, the processing system 100 may provide for an integrated solution for some processing of substrates.

Examples of a processing system that may be suitably modified in accordance with the teachings provided herein include the Endura®, Producer® or Centura® integrated processing systems or other suitable processing systems commercially available from Applied Materials, Inc., located in Santa Clara, California. It is contemplated that other processing systems (including those from other manufacturers) may be adapted to benefit from aspects described herein.

In the illustrated example of FIG. 1, the factory interface 102 includes a docking station 132 and factory interface robots 134 to facilitate transfer of substrates. The docking station 132 is adapted to accept one or more front opening unified pods (FOUPs) 136. In some examples, each factory interface robot 134 generally includes a blade 138 disposed on one end of the respective factory interface robot 134 adapted to transfer the substrates from the factory interface 102 to the load lock chambers 104, 106.

The load lock chambers 104, 106 have respective ports 140, 142 coupled to the factory interface 102 and respective ports 144, 146 coupled to the transfer chamber 108. The transfer chamber 108 further has respective ports 148, 150 coupled to the holding chambers 116, 118 and respective ports 152, 154 coupled to processing chambers 120, 122. Similarly, the transfer chamber 110 has respective ports 156, 158 coupled to the holding chambers 116, 118 and respective ports 160, 162, 164, 166 coupled to processing chambers 124, 126, 128, 130. The ports 144, 146, 148, 150, 152, 154, 156, 158, 160, 162, 164, 166 can be, for example, slit valve openings with slit valves for passing substrates therethrough by the transfer robots 112, 114 and for providing a seal between respective chambers to prevent a gas from passing between the respective chambers. Generally, any port is open for transferring a substrate therethrough. Otherwise, the port is closed.

The load lock chambers 104, 106, transfer chambers 108, 110, holding chambers 116, 118, and processing chambers 120, 122, 124, 126, 128, 130 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 134 transfers a substrate from a FOUP 136 through a port 140 or 142 to a load lock chamber 104 or 106. The gas and pressure control system then pumps down the load lock chamber 104 or 106. The gas and pressure control system further maintains the transfer chambers 108, 110 and holding chambers 116, 118 with an interior low pressure or vacuum environment (which may include an inert gas). Hence, the pumping down of the load lock chamber 104 or 106 facilitates passing the substrate between, for example, the atmospheric environment of the factory interface 102 and the low pressure or vacuum environment of the transfer chamber 108.

With the substrate in the load lock chamber 104 or 106 that has been pumped down, the transfer robot 112 transfers the substrate from the load lock chamber 104 or 106 into the transfer chamber 108 through the port 144 or 146. The transfer robot 112 is then capable of transferring the substrate to and/or between any of the processing chambers 120, 122 through the respective ports 152, 154 for processing and the holding chambers 116, 118 through the respective ports 148, 150 for holding to await further transfer. Similarly, the transfer robot 114 is capable of accessing the substrate in the holding chamber 116 or 118 through the port 156 or 158 and is capable of transferring the substrate to and/or between any of the processing chambers 124, 126, 128, 130 through the respective ports 160, 162, 164, 166 for processing and the holding chambers 116, 118 through the respective ports 156, 158 for holding to await further transfer. The transfer and holding of the substrate within and among the various chambers can be in the low pressure or vacuum environment provided by the gas and pressure control system.

The processing chambers 120, 122, 124, 126, 128, 130 can be any appropriate chamber for processing a substrate. In some examples, the processing chamber 120 can be capable of performing an etch process, the processing chamber 122 can be capable of performing a cleaning process, the processing chamber 124 can be capable of performing a selective removal process, and the processing chambers 126, 128, 130 can be capable of performing respective epitaxial growth processes. The processing chamber 120 may be a Selectra™ Etch chamber available from Applied Materials of Santa Clara, Calif. The processing chamber 122 may be a SiCoNi™ Pre-clean chamber available from Applied Materials of Santa Clara, Calif. The processing chamber 126, 128, or 130 may be a Centura™ Epi chamber, an Exsel chamber, or a Tersa chamber available from Applied Materials of Santa Clara, Calif.

A system controller 168 is coupled to the processing system 100 for controlling the processing system 100 or components thereof. For example, the system controller 168 may control the operation of the processing system 100 using a direct control of the chambers 104, 106, 108, 110, 116, 118, 120, 122, 124, 126, 128, 130 of the processing system 100 or by controlling controllers associated with the chambers 104, 106, 108, 110, 116, 118, 120, 122, 124, 126, 128, 130. In operation, the system controller 168 enables data collection and feedback from the respective chambers to coordinate performance of the processing system 100.

The system controller 168 generally includes a central processing unit (CPU) 170, memory 172, and support circuits 174. The CPU 170 may be one of any form of a general purpose processor that can be used in an industrial setting. The memory 172, or non-transitory computer-readable medium, is accessible by the CPU 170 and may be one or more of memory such as random access memory (RAM), read only memory (ROM), floppy disk, hard disk, or any other form of digital storage, local or remote. The support circuits 174 are coupled to the CPU 170 and may comprise cache, clock circuits, input/output subsystems, power supplies, and the like. The various methods disclosed herein may generally be implemented under the control of the CPU 170 by the CPU 170 executing computer instruction code stored in the memory 172 (or in memory of a particular processing chamber) as, for example, a software routine. When the computer instruction code is executed by the CPU 170, the CPU 170 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 108, 110 and the holding chambers 116, 118. In other examples, more or fewer transfer chambers (e.g., one transfer chamber) and/or more or fewer holding chambers (e.g., no holding chambers) may be implemented as a transfer apparatus in a processing system.

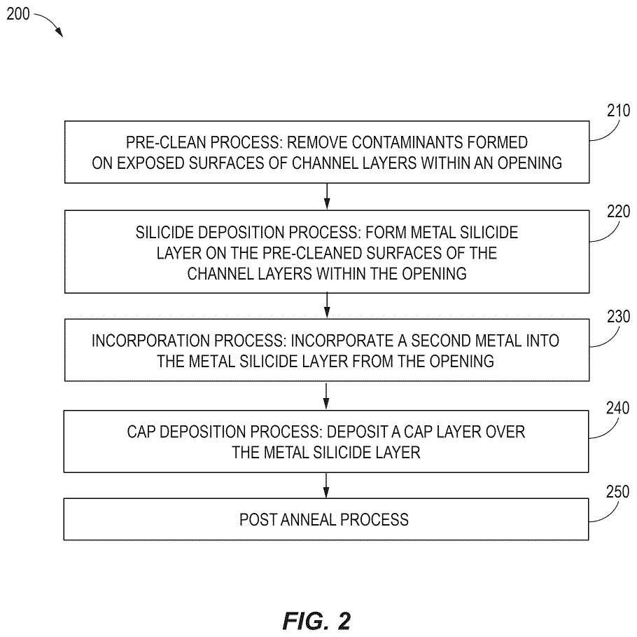

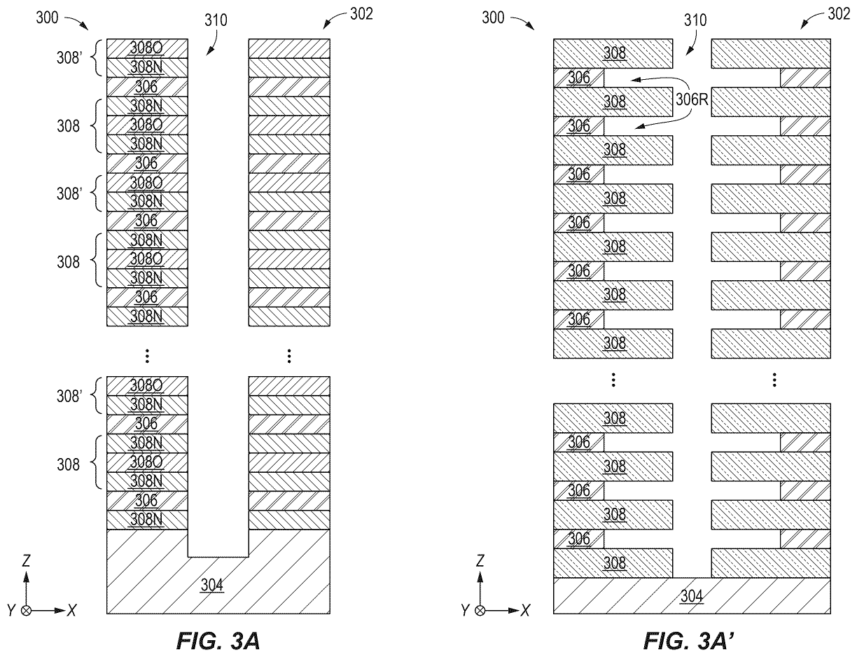

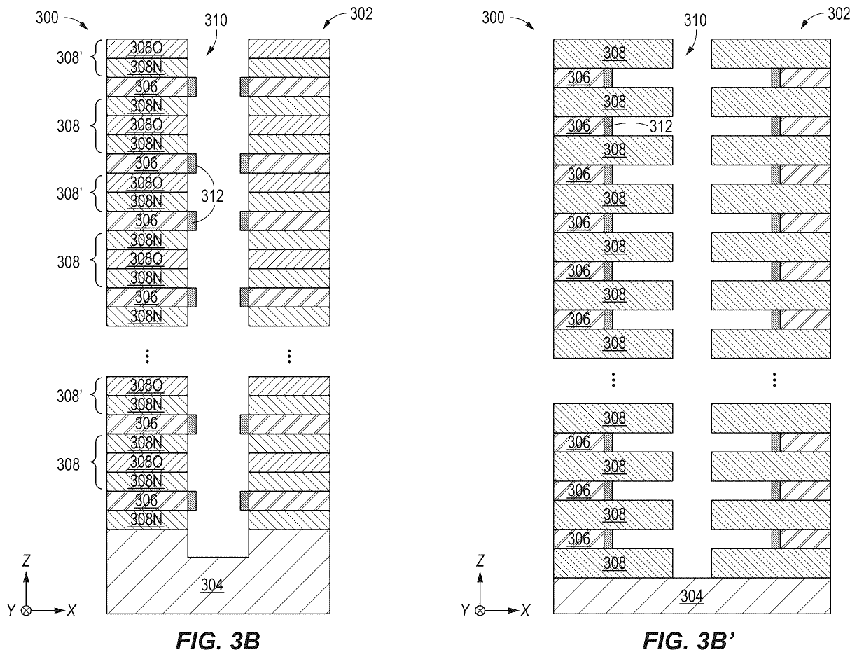

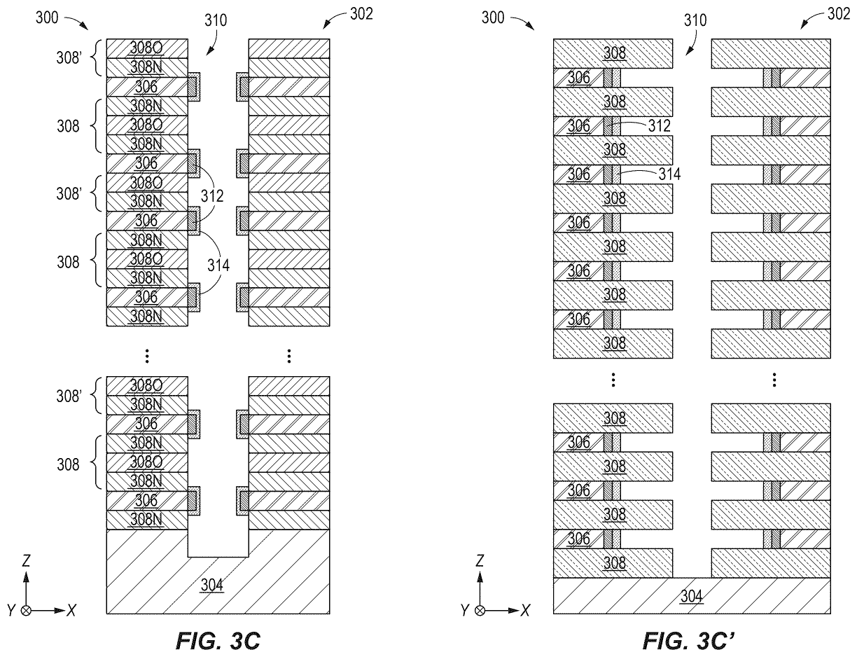

FIG. 2 depicts a process flow diagram of a method 200 of forming a composite metal silicide layer in a semiconductor structure 300 according to some embodiments of the present disclosure. The semiconductor structure 300 may be a portion of a three dimensional (3D) dynamic random access memory (DRAM) device. FIGS. 3A, 3A′, 3B, 3B′, 3C, and 3C′ are cross-sectional views of a portion of the semiconductor structure 300 corresponding to various states of the method 200. It should be understood that FIGS. 3A, 3A′, 3B, 3B′, 3C, and 3C′ illustrate only partial schematic views of the semiconductor structure 300, and the semiconductor structure 300 may contain any number of transistor sections and additional materials having aspects as illustrated in the figures. It should also be noted that although the method illustrated in FIG. 2 is described sequentially, other process sequences that include one or more operations that have been omitted and/or added, and/or have been rearranged in another desirable order, fall within the scope of the embodiments of the disclosure provided herein.

As shown in FIG. 3A, the semiconductor structure 300 includes a layer stack 302 formed on a substrate 304. An opening 310 (e.g., a hole or a trench) is formed extending through the layer stack 302. The layer stack 302 includes alternating channel layers 306 and dielectric layers 308, 308′ stacked in the Z direction. The channel layers 306 may be formed of silicon(S), each having a thickness of between about 10 nm and about 100 nm, for example, about 50 nm. Each dielectric layer 308 may include a stack of nitride layers 308N formed of silicon nitride (Si₃N₄) and an oxide layer 308O formed of silicon oxide (SiO₂), each having a thickness of between about 10 nm and about 100 nm, for example, about 50 nm. Each dielectric layer 308′ may include a stack of a nitride layer 308N formed of silicon nitride (Si₃N₄) and an oxide layer 308O formed of silicon oxide (SiO₂), each having a thickness of between about 10 nm and about 100 nm, for example, about 50 nm. Thus, inner surfaces of the opening 310 include silicon surfaces (exposed surfaces of the channel layers 306) and dielectric surfaces (exposed surfaces of the dielectric layers 308, 308′). In some embodiments, as shown in FIG. 3A′, the layer stack 302 includes alternating channel layers 306 and dielectric layers 308. Each of the dielectric layers 308 are formed of silicon nitride (Si₃N₄) or silicon oxide (SiO₂) having a thickness of between about 10 nm and about 100 nm, for example, about 50 nm. The channel layers 306 may be recessed from the opening 310, each recess 306R having a depth of between about 10 nm and about 100 nm, for example, about 50 nm. Inner surfaces of the opening 310 include silicon surfaces (exposed surfaces of the channel layers 306) and dielectric surfaces (exposed surfaces of the dielectric layers 308).

The opening 310 has a critical dimension of between about 100 nm and about 150 nm, a depth of between about 4 μm and 8 μm, and thus aspect ratio of between about 1:60 and about 1:80 or higher.

The term “substrate” as used herein refers to a layer of material that serves as a basis for subsequent processing operations and includes a surface to be cleaned. The substrate may be a silicon based material or any suitable insulating materials or conductive materials as needed. The substrate may include a material such as crystalline silicon (e.g., Si<100>or Si<111>), silicon oxide, strained silicon, silicon germanium, doped or undoped polysilicon, doped or undoped silicon wafers and patterned or non-patterned wafers, silicon on insulator (SOI), carbon doped silicon oxides, silicon nitride, doped silicon, germanium, gallium arsenide, glass, or sapphire.

The method 200 begins with a pre-clean process in block 210. The pre-clean process may be performed in a processing chamber, such as the processing chamber 122 shown in FIG. 1.

The pre-clean process is configured to remove contaminants, such as carbon-containing contaminants (e.g., patterning residues), or oxide-containing contaminants (e.g., native oxide layers) formed on exposed surfaces of the channel layers 306 within the opening 310.

The pre-clean process to remove oxide-containing contaminants may include an isotropic etch process, such as a wet etch process using distilled hydrofluoric acid (d-HF) solution, or a dry chemical etch process using ammonia (NH₃) and hydrofluoric acid (HF). The etch process is selective for oxide layers, and thus does not readily etch silicon, germanium, or nitride layers regardless of whether the layers are amorphous, crystalline or polycrystalline. Selectivity of the etch process for oxide versus silicon or germanium is at least about 3:1, and usually 5:1 or better, sometimes 10:1.

The pre-clean process to remove carbon-containing contaminants may include an anisotropic remote plasma assisted dry etch process, such as a reactive ion etching (RIE) process, using a plasma formed from a gas including hydrogen (H), argon (Ar), helium (He), or a combination thereof.

In block 220, a silicide deposition process is performed to form a metal silicide layer 312 selectively on the pre-cleaned surfaces of the channel layers 306 within the opening 310, as shown in FIGS. 3B and 3B′. The metal silicide layer 312 may be formed of silicide of a first metal (e.g., molybdenum (Mo)) (e.g., molybdenum silicide (MoSiₓ, x~0-3)), having a thickness of between about 5 Å and about 100 Å, for example, about 50 Å. It has been known that molybdenum silicide (MoSiₓ) has deposition selectivity on silicon surfaces (e.g., exposed surfaces of the channel layers 306) over dielectric surfaces (e.g., exposed surfaces of the dielectric layers 308, 308′) with uniformity from the bottom to the top of the opening 310. The silicide deposition process may include chemical vapor deposition (CVD), performed in a processing chamber, such as the processing chamber 126, 128, or 130 shown in FIG. 1.

During the deposition process, a precursor containing the first metal (e.g., molybdenum (Mo)), such as molybdenum (Mo)-containing halide precursor (e.g., molybdenum pentachloride (MoCl₅), molybdenum oxytetrachloride (MoOCl₄)), and hydrogen (H₂) precursor are flowed in the processing chamber.

The deposition process may be performed at a first deposition temperature of between about 320° C. and about 450° C. at a pressure of between 3 Torr and 300 Torr. During the deposition process, hydrogen (H₂) gas may be supplied at a flow rate of between about 0 sccm and about 15000 sccm.

After a cycle of the deposition process, one or more cycles are repeated with a purge between cycles, until a desired thickness of the metal silicide layer 312 is achieved. During the purge, a purge gas, which can be argon (Ar), is introduced in the processing chamber. In some embodiments, the purge gas includes hydrogen (H₂) gas.

In block 230, an incorporation process is performed to incorporate a second metal (e.g., titanium (Ti)) into the metal silicide layer 312 from the opening 310. The metal silicide layer 312, after incorporation of the second metal (e.g., titanium (Ti)), exhibits properties of silicide of the second metal (e.g., titanium (Ti), zirconium (Zr), hafnium (Hf), yttrium (Y)) (e.g., titanium silicide (TiSi_{y}, y~0-3), zirconium silicide (ZiSi_{y}, y~0-3), hafnium silicide (TiSi_{y}, y~0-3), yttrium silicide (TiSi_{y}, y~0-3)). It has been known that titanium silicide (TiSi_{y}) has low contact resistance R_{C} and high thermal stability as compared to molybdenum silicide (MoSiₓ). Thus, the composite metal silicide layer 312 (e.g., MoSiₓ:Ti) with the second metal (e.g., titanium (Ti)) incorporated has lower contact resistance R_{C} and higher thermal stability than the metal silicide layer 312 without the second metal (e.g., titanium (Ti)) incorporated. Concentration of second metal (e.g., titanium (Ti), zirconium (Zr), hafnium (Hf), yttrium (Y)) within the composite metal silicide layer 312 varies across a thickness of the composite metal silicide layer 312, with lower concentration near the silicon surfaces of the opening 310 and higher concentration away from the silicon surfaces of the opening 310. The incorporation process may include chemical vapor deposition (CVD), performed in a processing chamber, such as the processing chamber 126, 128, or 130 shown in FIG. 1.

During the incorporation process, a precursor containing the second metal (e.g., titanium (Ti)), such as titanium (Ti)-containing halide precursor (e.g., titanium tetrachloride (TiCl₄)), and hydrogen (H₂) precursor are flowed in the processing chamber.

The incorporation process may be performed at a second deposition temperature of between about 500° C. and about 675° C. at a pressure of between 3 Torr and 300 Torr. During the incorporation process, hydrogen (H₂) gas may be supplied at a flow rate of between about 0 sccm and about 15000 sccm.

After a cycle of the deposition process, one or more cycles are repeated with a purge between cycles, until a desired incorporation of the second metal into the metal silicide layer 312 is achieved. During the purge, a purge gas, which can be argon (Ar), is introduced in the processing chamber. In some embodiments, the purge gas includes hydrogen (H₂) gas.

In block 240, a cap deposition process is performed, in which a cap layer 314 is deposited over the metal silicide layer 312, as shown in FIGS. 3C and 3C′. The cap deposition process may include any appropriate deposition process, such as chemical vapor deposition (CVD), or physical vapor deposition (PVD), performed in a processing chamber, such as the processing chamber 126, 128, or 130 shown in FIG. 1. The cap layer 314 may be formed of titanium nitride (TiN), combination of titanium nitride (TiN) and tungsten (W), tungsten (W), molybdenum (Mo), or silicon (Si). The cap layer 314 may prevent oxidation of the metal silicide layer 312 during a subsequent anneal process.

In block 250, a post anneal process may be performed to improve properties of the metal silicide layer 312 or the cap layer 314. The post anneal process may include a thermal anneal process in reducing environment that includes silane (SiH₄), hydrogen (H₂), ammonia (NH₃), a mixture thereof, and inert gas (e.g., helium (He), argon (Ar)) and other noble gas, performed in a rapid thermal processing (RTP) chamber, such as the processing chamber 120, 122, 124, 126, 128, or 130 shown in FIG. 1. The thermal anneal process may be performed for between about 0 second and about 7200 seconds, at a temperature of between about 500° C. and about 700° C., and at a pressure of between about 0.05 Torr and 300 Torr, repeated for about 1 and about 100 cycles.

The embodiments described herein provide composite metal silicide (e.g., titanium (Ti)-incorporated molybdenum silicide (MoSiₓ: Ti)) and methods for forming thereof within a deep opening (e.g., a hole or a trench) that can be used to reduce a contact resistance in three dimensional (3D) dynamic random access memory (DRAM) devices or multi-gate metal-oxide-semiconductor field-effect transistors (MOSFETs). The composite metal silicide (e.g., titanium (Ti)-incorporated molybdenum silicide (MoSiₓ: Ti)) provides benefits of both of single-composition silicides (e.g., molybdenum silicide (MoSiₓ) and titanium silicide (TiSiₓ)), having good selectivity, uniformity, and thermal stability when deposited on inner sidewalls of deep holes or deep trenches, and providing a low contact resistivity.

The methods of forming composite metal silicide includes first forming metal silicide (e.g., molybdenum silicide (MoSiₓ)) that can ensure good selectivity, and then incorporating additional metal species (e.g., titanium (Ti)) to improve contact resistivity and thermal stability.

While the foregoing is directed to embodiments of the present disclosure, other and further embodiments of the disclosure may be devised without departing from the basic scope thereof, and the scope thereof is determined by the claims that follow. Claims:

1. A semiconductor structure, comprising:
a layer stack on a substrate, wherein an opening extends through the layer stack, inner surfaces of the opening comprising silicon surfaces and dielectric surfaces; and
a composite metal silicide layer on the silicon surfaces of the opening, wherein the composite metal silicide layer comprises titanium-incorporated molybdenum silicide.

2. The semiconductor structure of claim 1, wherein a concentration of titanium varies across a thickness of the composite metal silicide layer.

3. The semiconductor structure of claim 1, wherein:
the layer stack comprises alternating channel layers and dielectric layers.

4. The semiconductor structure of claim 3, wherein:
the channel layers each comprise silicon(S), having thickness of between 10 nm and 100 nm.

5. The semiconductor structure of claim 3, wherein:
the dielectric layers each comprise a stack of nitride layers and an oxide layer, each having a thickness of between 10 nm and 100 nm.

6. The semiconductor structure of claim 3, wherein:
the dielectric layers each comprise silicon nitride (Si₃N₄) or silicon oxide (SiO₂) having a thickness of between 10 nm and 100 nm, and
the channel layers each have a recess formed from the opening, each recess having a depth of between 10 nm and 100 nm.

7. The semiconductor structure of claim 1, further comprising:
a cap layer on the composite metal silicide layer, wherein the cap layer comprises titanium nitride (TiN).

8. A method of forming a composite metal silicide layer in a semiconductor structure, comprising:
performing a silicide deposition process in a processing chamber, in which a metal silicide layer of silicide of a first metal is selectively formed on silicon surfaces within an opening formed in a semiconductor structure, inner surfaces of the opening comprising the silicon surfaces and dielectric surfaces; and
performing an incorporation process in the processing chamber, in which a second metal is incorporated into the metal silicide layer,
wherein the first metal comprises molybdenum (Mo) and the second metal comprises titanium (Ti).

9. The method of claim 8, wherein the metal silicide layer has a thickness of between 5 Å and 100 Å.

10. The method of claim 8, wherein the silicide deposition process comprises a vapor deposition (CVD) process.

11. The method of claim 8, wherein the incorporation process comprises a vapor deposition (CVD) process.

12. The method of claim 8, further comprising:
prior to the silicide deposition process, performing a pre-cleaning process to remove contaminants on the silicon surfaces within the opening.

13. The method of claim 8, further comprising:
subsequent to the incorporation process, performing a cap deposition process, in which a cap layer is deposited on the metal silicide layer, wherein
the cap layer comprises titanium nitride (TiN).

14. The method of claim 13, further comprising:
subsequent to the cap deposition process, performing a post-anneal process.

15. A method of forming a composite metal silicide layer in a semiconductor structure, comprising:
removing contaminants on silicon surfaces within an opening formed in a semiconductor structure, inner surfaces of the opening comprising the silicon surfaces and dielectric surfaces;
depositing a metal silicide layer comprising silicide of a first metal on the silicon surfaces within the opening using a precursor containing the first metal at a first deposition temperature;
incorporating a second metal into the metal silicide layer using a precursor containing the second metal at a second deposition temperature;
depositing a cap layer on the metal silicide layer; and
performing a post annealing process.

16. The method of claim 15, wherein the metal silicide layer has a thickness of between 10 Å and 100 Å.

17. The method of claim 15, wherein the first metal comprises molybdenum silicide and the second metal comprises titanium.

18. The method of claim 15, wherein:
the first deposition temperature is between 320° C. and about 450° C., and
the second deposition temperature is between 500° C. and 675° C.

19. The method of claim 15, wherein depositing the metal silicide layer and incorporating the second metal into the metal silicide layer each comprise a vapor deposition (CVD) process.

20. The method of claim 15, wherein the cap layer comprises titanium nitride (TiN).
